(19) United States
(12) Patent Application Publication
(10) Pub. No.: US 2001/0029114 A1
(43) Pub. Date: Oct. 11, 2001

(54) Method of forming polymeric layers of silicon oxynitride

(76) Inventors: Michele Vulpio, Santo Spirito (IT); Cosimo Gerardi, San Pietro Vernotico (IT)

Correspondence Address: SEED INTELLECTUAL PROPERTY LAW GROUP PLLC, 701 FIFTH AVE, SUITE 6300, SEATTLE, WA, 98104-7092, US

(21) Appl. No.: 09/796,723

(22) Filed: Feb. 27, 2001

(30) Foreign Application Priority Data
Feb. 29, 2000 (EP) 00830152.5

(51) Int. Cl. H01L 21/31; H01L 21/469

(52) U.S. Cl. 438/794; 438/790

(57) ABSTRACT

A method of deposits polymeric layers of silicon oxynitride onto a surface of a semiconductor material substrate by a Chemical Vapor Deposition technique using at least one organosilane chemical precursor. In some embodiments, the organosilane comprises a combination of silicon, nitrogen, carbon and hydrogen, a specific example of which can be hexamethyldisiloxane. This technique can be used for all standard types of deposition, LPCVD, APCVD, SACVD and PECVD. Using HMDSN provides more uniform layers to be formed on the substrate, with increased quality. Specifically, step-coverage is better than in prior techniques, there is more uniformity of the layers, parameters of the deposition are easier to control, there is improved stoichiometry in the formed layers, and the production process uses materials that are more environmentally healthy than those used previously.

### TECHNICAL FIELD

This invention relates to a method of depositing polymeric layers of silicon oxynitride onto a semiconductor by a Chemical Vapor Deposition technique, specifically for fabricating Very Large Scale Integration electronic circuits.

### BACKGROUND OF THE INVENTION

Silicon oxynitride is a highly important material to the insulating technology currently employed for fabricating Very Large Scale Integration (VLSI) electronic circuits. Films of this oxynitride are also widely used for outer passivation layers to protect devices formed on a semiconductor from contamination. Other possible applications include glare preventing coatings for solar cells, etc., and for thin active dielectrics used in VLSI-CMOS technology.

Some methods are known from literature and currently practiced for depositing films of silicon oxide (SiO₂) and oxynitride (Si₂O₆N) using Chemical Vapor Deposition (CVD) techniques such as SACVD (Sub-Atmospheric CVD), PECVD (Plasma Enhanced CVD), LPCVD (Low Pressure CVD), APCVD (Atmospheric Pressure CVD), and HDP-CVD (High Density Plasma CVD). Chemical compounds known as precursors are used to initiate the film depositing process. These compounds contain the chemical elements that are used to eventually form the chemical backbone of the finished film.

For depositing films of silicon oxide, either precursors based on compounds containing an organic part and an inorganic part (known as organosilanes), or a mixture of silane (SiH₄) and oxygen (O₂) are typically used. Typical organosilanes containing an organic part are HMDSN (hexamethyldisilazane) and HMDSO (hexamethyldisiloxane), having the group CH₃ as their organic part, and TEOS (tetraethylorthosilicate) having the group CH₃CH₂ as its organic part. These compounds are used, in particular, with the SACVD, PECVD and LPCVD techniques. Silane and oxygen are used with the APCVD, LPCVD and HDP-CVD techniques. A chemical structure diagram of hexamethyldisilazane is shown in FIG. 1.

For depositing oxynitride films, mixtures of silane (SiH₄) and nitrogen dioxide (N₂O) are used, and for plasma deposition, ammonia (NH₃) and nitrogen (N₂) are used.

However, the use of silane gas has several drawbacks. Silane is a dangerous gas and produces uneven films. In addition, CVD techniques require a high reaction temperature, which can oftentimes harm the substrate, especially where the finished films are used as pre-metallization (PMD) or inter-metallization (IMD) dielectric layers, or as dielectric layers in VLSI circuits. Moreover, the reactions are very slow in all of the above instances.

Methods of depositing silicon oxynitride by PECVD are described in U.S. Pat. No. 4,599,678 (Wertheimer et al.) and U.S. Pat. No. 4,673,588 (Bringmann et al.). The former of these documents discloses a thin film of oxynitride dielectric deposited by PECVD. The deposition is initiated using HMDSO and HMDSN as precursors. The latter document relates to a method of applying polymeric coatings to a substrate by PECVD depositing HMDSN, a polymerizable gas. This gas is preferred because it is far less toxic than the silane gas usually employed in deposition processes, and its use offers additional advantages. It is reported by Hieber et al. (U.S. Pat. No. 5,399,389) that, for depositing silicon oxide (SiO₂) films, the use of HMDSO, which is very similar to HMDSN, as a precursor instead of TEOS improves the rate of deposition. Many other references point to these monomers yielding films which exhibit improved physical characteristics, such as a higher density with respect to films formed from silane.

However, PECVD deposition is affected by some significant problems, such as uncontrolled film stoichiometry and plasma damaging, which greatly restrict the application of such a method to all metallization levels.

Thus, there exists a need for chemical compounds which are less toxic and technically more convenient for use in the electronic industry.

### SUMMARY OF THE INVENTION

Embodiments of the invention use a technique for depositing silicon oxynitride films using a technique and a chemical precursor effective to yield a uniform film and provide for improved processing conditions. They do this by depositing a layer of silicon oxynitride through the CVD technique using HMDSN as the precursor. Whereas the deposition of oxynitride by SiH4, N₂O and NH₃ activated CVD requires a very high temperature process (about 900° C.), the deposition with CVD techniques of oxynitride activated by HMDSN can be carried out at a much lower temperature (e.g., about 550° C. using the SACVD, Sub-Atmospheric CVD technique). Embodiments of the invention, therefore, use HMDSN as a CVD deposition precursor.

The features and advantages of a method according to the invention will be apparent from the following description of an embodiment thereof, given by way of example and not of limitation.

### BRIEF DESCRIPTION OF THE DRAWINGS

FIG. 1 is a chemical structure diagram showing the structure of hexamethyldisilazane.

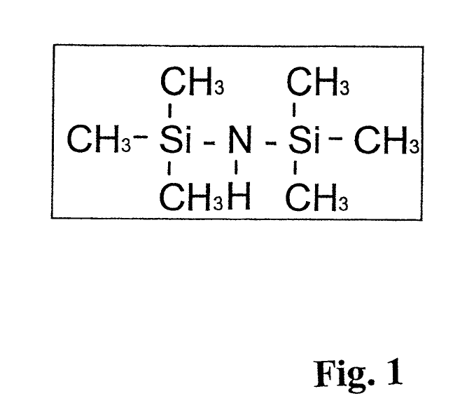

FIG. 2 is a block diagram showing components of a CVD apparatus.

### DETAILED DESCRIPTION OF THE INVENTION

The process steps and the structures described herein below are not exhaustive of a process for fabricating integrated circuits. This invention can be practiced together with integrated circuit fabrication techniques currently employed in the industry, and only such conventional process steps as are deemed necessary to an understanding of the invention will be discussed. Discussion of techniques or structures well known to those skilled in the art has been eliminated for brevity and so as not to obfuscate the inventive concept. A general background discussion of Chemical Vapor Deposition is made in chapter 12 (pps 351-387) of Microchip Fabrication, third edition by Peter Van Zant, McGraw-Hill, 1997, which is specifically incorporated herein in its entirety.

Disclosed methods allows silicon oxynitride films to be deposited by a CVD technique using a hexamethyldisilazane (Si₂NC₄H₁₉) monomer gas, also known by its acronym HMDSN, as a chemical precursor. In this monomer, the nitrogen atom is strongly bonded to the two silicon atoms in that a free electron pair of the nitrogen atoms can be shared with the silicon atoms. Because silicon has “d” orbitals free, it can stabilize this bond through another resonant structure wherein the nitrogen atom shares the electron pair with the silicon atoms. This structure weakens the N—H bond which will be, therefore, weaker than the N—H bond of ammonia. This is confirmed by the fact that the proportion of N—H bonds in plasma-formed films using this monomer is always quite small. A possible embodiment of the inventive method is the HMDSN exploitation as a precursor in ozone-activated SACVD. In this case, the reaction stoichiometry is:

4HMDSN+43O₂→16CO₂+38H₂O+4[Si₂O₆N]

This reaction yields a deposition precursor where silicon atoms are allowed to react with oxygen radicals, provided in the reaction, to yield a film of silicon oxynitride.

Thus, the use of HMDSN leads to a faster deposition process and an increased density of the deposited film. It is known (e.g., from the aforementioned U.S. Pat. No. 5,399,389) that where silicon oxide (SiO₂) films are to be deposited, the use of HMDSO as a precursor instead of TEOS enhances the rate of deposition. Furthermore, it is reported in several articles that the HMDSN and HMDSO monomers yield films with improved physical characteristics, such as a superior quality and uniformity of the film compared to films deposited by a conventional technique using TEOS. Moreover, the deposition process can be run at a lower temperature and higher deposition rate by virtue of the structure of HMDSN containing two silicon atoms instead of the single atom of TEOS.

Compared with silicon oxynitride films deposited by PE-CVD, those that use the HMDSN precursor have several advantageous properties. For instance, the same HMDSN monomer can be used with many different techniques, such as LPCVD, APCVD, as well as SACVD. When using SACVD, step coverage of the silicon oxynitride films is increased. There is a greater uniformity of films throughout the deposition area when using HMDSN as the precursor. Additionally, when using the HMDSN precursor with the LPCVD, APCVD and SACVD techniques, there are more external parameters available for better control, such as IR, stress, etc. Further, there is better stoichiometry when using these techniques. Finally, using HMDSN as a precursor is much better on the environment than using Silane, which can generate harmful byproducts.

In addition, the inventive method can be easily implemented in the process steps made available by conventional VLSI technology, using some typical process parameters. In particular, the chemicals used are HMDSN, N₂O or O₃, N₂ and O₂. The process temperature and pressure are within the range of 550° to 1000° C., and 0.1 to 3 bar, respectively. The rate of deposition of the film onto silicon varies between 0.5 and 200 nm/minute.

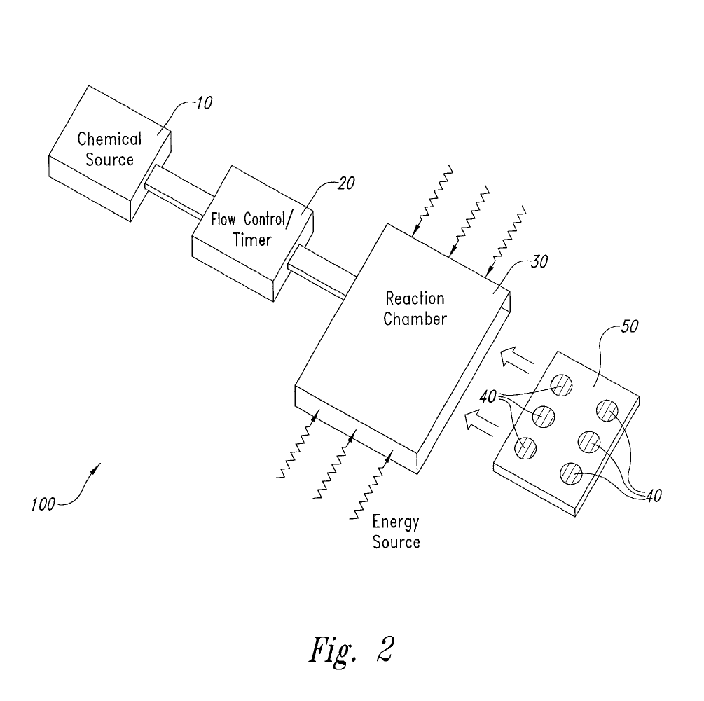

Shown in FIG. 2 is an example standard CVD system 100 useful for embodiments of the invention. A chemical source 10 provides the precursors and other materials needed to generate the vapors used for deposition. Examples of the precursors can include HMDSN, TEOS, Oxygen, and Silane, as well as other materials. These sources are passed through a flow control/timer section 20, where the mixing portions and timings of the precursor chemicals are controlled. Then, the reactants flow to a reaction chamber 30, which can be a vessel where atmospheric pressure is controllable. The reaction chamber 30 may receive energy from an energy source, such as heat by convection, IR, etc. Wafers 40, which can be silicon or other conductive, semiconductive, or insulative material are placed into a tray 50 and inserted into the reaction chamber 30. While in the reaction chamber 30, the wafers 40 are exposed to the chemical reactants which cause deposition of some of the reactants onto the wafers, thereby altering their chemical and physical properties.

Changes can be made to the invention in light of the above detailed description. In general, in the following claims, the terms used should not be construed to limit the invention to the specific embodiments disclosed in the specification and the claims, but should be construed to include all methods and devices that are in accordance with the claims. Accordingly, the invention is not limited by the disclosure, but instead its scope is to be determined by the following claims.

We claim:

1. A method of forming a film on a surface of a semiconductor substrate comprising depositing polymeric layers of silicon oxynitride onto the surface by a non-plasma-enhanced Chemical Vapor Deposition technique using an organosilane as a chemical precursor.

2. The method according to claim 1 wherein the organosilane comprises a combination of silicon, nitrogen, carbon and hydrogen.

3. The method according to claim 1 wherein the organosilane is HMDSN.

4. The method according to claim 3 wherein the deposition of the layers using the HMDSN precursor takes place at a process temperature above 400° C.

5. The method according to claim 3 wherein the deposition of the layers using the HMDSN precursor takes place at a process temperature between about 400° C. to 1000° C.

6. The method according to claim 1 wherein depositing polymeric layers comprises depositing polymeric layers using HMDSN at a process pressure of about 0.1 to 3 bar.

7. The method according to claim 3 wherein depositing polymeric layers comprises depositing polymeric layers using HMDSN at a rate of about 0.5 to 200 nm/minute.

8. The method according to claim 1 wherein the organosilane precursor is HMDSN and wherein the Chemical Vapor Deposition process is a Sub-Atmospheric Chemical Vapor Deposition process activated by an oxygen compound.

9. The method according to claim 8, wherein in the oxygen compound is ozone.

10. A method of forming a layer of silicon oxynitride on a surface of a substrate material, comprising:
combining, in a Chemical Vapor Deposition apparatus, one or more precursor materials, at least one of which is an organosilane;
causing a chemical vapor to be formed from the one or more precursor materials;
maintaining the chemical vapor in a non-plasma state;
inserting the substrate material into a reaction chamber portion of the Chemical Vapor Deposition apparatus; and
routing the chemical vapor to the reaction chamber to contact the surface of the substrate material.

11. The method of claim 10 wherein combining one or more precursor materials comprises combining HMDSN.

12. The method of claim 10 wherein combining one or more precursor materials comprises combining HMDSN at a temperature in the range of about 400° C.-1000° C.

13. The method of claim 10 wherein combining one or more precursor materials comprises combining HMDSN at a pressure in the range of about 0.1 to 3 bar.

14. The method of claim 10 wherein the substrate is semiconductive.

15. A method of forming a layer of silicon oxynitride on a surface of a semiconductor substrate material, comprising:
combining, in a Chemical Vapor Deposition apparatus, two or more precursor materials, comprising at least HMDSN and an oxygen compound;
causing a chemical vapor to be formed from the precursor materials;
maintaining the formed chemical vapor in a non-plasma state;
inserting the substrate material into a reaction chamber portion of the Chemical Vapor Deposition apparatus;
routing the chemical vapor to the reaction chamber to contact the surface of the substrate material; and
controlling a flow rate of the formed chemical vapor so as to limit the formation of the silicon oxynitride layer to a rate between about 0.5 to 200 nm/minute

16. The method of claim 15 wherein the precursor materials are combined in a Sub Atmospheric Chemical Vapor Deposition apparatus.

17. The method of claim 15 wherein the precursor materials are combined at a temperature in the range between about 400° C.-1000° C.

18. A semiconductor substrate formed by:
combining, in a Chemical Vapor Deposition apparatus, two or more precursor materials, comprising at least HMDSN and an oxygen compound;
causing a chemical vapor to be formed from the precursor materials;
maintaining the formed chemical vapor in a non-plasma state;
inserting the substrate material into a reaction chamber portion of the Chemical Vapor Deposition apparatus; and
routing the chemical vapor to the reaction chamber to contact the surface of the substrate material.

19. The method of claim 18 wherein the precursor materials are combined in a Sub Atmospheric Chemical Vapor Deposition apparatus.

20. The method of claim 18 wherein the precursor materials are combined at a temperature in the range between about 400° C.-1000° C.
